(19) United States
(12) Patent Application Publication
(10) Pub. No.: US 2026/0219588 A1
(43) Pub. Date: Jul. 30, 2026

(54) EUV MIRROR, INSPECTION SYSTEM, MASK INSPECTION APPARATUS, METHOD FOR EXAMINING AN EUV MIRROR

(71) Applicant: Carl Zeiss SMT GmbH, Oberkochen (DE)

(72) Inventors: Henri Schottmueller, Aalen (DE); Soeren Knorr, Aalen (DE); Jan Kessler, Gerstetten (DE)

(21) Appl. No.: 19/460,730

(22) Filed: Jan. 27, 2026

(30) Foreign Application Priority Data
Jan. 28, 2025 (DE) 102025102955.5

(51) Int. Cl. G03F 7/00

(52) U.S. Cl. CPC G03F 7/70825; G03F 7/70316; G03F 7/7085

(57) ABSTRACT

The invention relates to an EUV mirror comprising a mirror body and a holding component, wherein the holding component is connected to the mirror body by way of an adhesive bond and wherein an optical surface with high reflectivity for EUV radiation is formed on the mirror body. The mirror body consists of a transparent material. The surface of the mirror body comprises a non-transparent surface region and a viewing window. The viewing window provides an observation channel to the adhesive bond. The invention also relates to an inspection system, a mask inspection apparatus and a method for examining an EUV mirror.

### CROSS-REFERENCE TO RELATED APPLICATION

This application claims benefit under 35 U.S.C. §119 to German Patent Application 102025102 955.5, filed on January 28, 2025, the entire content of which is incorporated herein by reference.

### TECHNICAL FIELD

The invention relates to an EUV mirror, an inspection system, a mask inspection apparatus and a method for examining an EUV mirror.

### BACKGROUND

Microlithographic photomasks are examined for structural defects in mask inspection apparatuses. In so doing, an EUV beam path starting at an EUV radiation source is guided to the photomask to be examined by way of an illumination system. The EUV beam path reflected off the photomask is subsequently imaged onto an image sensor of an EUV camera by way of a projection lens. The illumination system and the projection lens may comprise EUV mirrors off which the EUV beam path is reflected.

### SUMMARY

To ensure a high-quality EUV mirror optics unit, an EUV mirror must be held in a precisely predefined position relative to adjacent elements. Holding components for example in the form of fastening bushings are attached to the mirror body in order to be able to transmit the required forces between the mirror body and adjacent elements. The holding components may be connected to the mirror body by adhesive bonding.

Fault-free operation of the EUV mirror optics unit requires a reliable connection of the holding component relative to the mirror body. The EUV mirror optics unit operation may be adversely affected by the holding component detaching from the mirror body or by a displacement of the holding component relative to the mirror body.

The problem addressed by the invention is that of presenting an EUV mirror, an inspection system, a mask inspection apparatus and a method for examining an EUV mirror which reduce the aforementioned disadvantages. The problem is solved by the features of the independent claims. Advantageous embodiments are specified in the dependent claims.

An EUV mirror according to the invention comprises a mirror body and a holding component, wherein the holding component is connected to the mirror body by way of an adhesive bond and wherein an optical surface with high reflectivity for EUV radiation is formed on the mirror body. The mirror body consists of a transparent material. The surface of the mirror body comprises a non-transparent surface region and a viewing window. The viewing window provides an observation channel to the adhesive bond.

The intention is for the invention to provide an option for detecting defects in the adhesive bond between the holding component and the mirror body. In principle, a visual inspection can be used to detect many adhesive bond defects, for example, a non-uniform distribution of the adhesive or foreign inclusions within the adhesive. However, a lateral view into the adhesive gap is usually not sufficient to this end; instead, a view of the adhesive bond surface is required in order to be able to identify adhesive bond defects by way of a visual inspection.

The invention proposes the creation of an observation channel which extends through the material of the mirror body to the adhesive bond. While the mirror body material is transparent per se, this is generally not the case for the mirror body surface. Processing steps causing a loss of transparency are usually performed on the mirror body surface during the production of an EUV mirror. In addition to a non-transparent surface region, the surface of the mirror body comprises a viewing window. The viewing window provides an observation channel, and so the adhesive bond is visible through the viewing window and can be examined.

Processing steps providing the mirror body with a desired geometric shape may be performed on the mirror body during the production of the EUV mirror. One of the processing steps may consist in grinding the surface. After grinding, the material may comprise a surface structure which presents an obstacle to a clear view into the depth of the material.

The viewing window may have been generated within the non-transparent surface region by way of a processing step that reduced the surface roughness. For example, the viewing window may be produced by polishing. The viewing window may be formed by a polished surface region of the mirror body.

The transparency of the material and of the material surface in the region of the viewing window allows the adhesive bond to be viewed along the observation channel. Accordingly, the material and/or the transparent surface region of the viewing window may be transparent to visible light in particular. In other words, the material and/or the surface region may be transparent to electromagnetic radiation within a wavelength range from 400 nm to 760 nm. A non-transparent surface region may be designed such that it scatters a greater proportion of the visible light than the transparent surface region. In general, an object located behind a non-transparent surface region cannot be identified clearly through said non-transparent surface region.

The area of the viewing window may adjoin the non-transparent surface region of the mirror body. In relation to a perimeter line of the viewing window, the boundary between the viewing window and the non-transparent surface region may make up at least 30% of the length of the perimeter line, preferably at least 60% of the length of the perimeter line and further preferably at least 90% of the length of the perimeter line. In one embodiment, the viewing window is located within the non-transparent surface region such that the viewing window is surrounded all around by the non-transparent surface region.

The non-transparent surface region of the mirror body is a surface region separate from the optical surface. The non-transparent surface region may make up at least 30%, preferably at least 50% and further preferably at least 80% of the surface of the mirror body, with the optical surface of the EUV mirror remaining excluded.

The holding component may be attached to a pin of the mirror body. The shape of the pin may be such that it projects from a main body of the mirror body. Alternatively, the pin may also be fully or partially recessed within the main body of the mirror body. In the case of a pin recessed in the main body, a cutout which extends like a ring around the lateral surface of the pin may be formed in the main body.

The pin may have an end face. The end face may be plane. The end face may make a right angle with the lateral surface. The end face may be aligned in parallel with a surface region of the mirror body surrounding the pin. The end face may be flush with the surrounding surface region of the mirror body. It is also possible for the end face to be located at a protruding position in relation to the surrounding surface region of the mirror body or at a recessed position in relation to the surrounding surface region of the mirror body.

The holding component may be attached to the end face of the pin. The adhesive bond may be formed between the end face of the pin and the holding component.

A pin cutout may be formed in the interior of the pin. The pin cutout may extend into the pin starting from the end face of the pin. The pin may be formed by a pin wall which extends around the pin cutout. The pin cutout may have the form of a bore which may be designed as a blind bore or as a through bore.

The holding component may comprise a projection which projects into the pin cutout. A collar may be formed on the holding component. The adhesive bond between the holding component and the mirror body may be established on a rear side of the collar. The collar may have a front side opposite the rear side. The front side may be aligned parallel to the end face of the pin.

The holding component may be in the form of a bushing. A receptacle configured for a connection to a counterpart may be formed in the interior of the bushing. The receptacle may be provided with structures that are provided for a mechanical connection with the counterpart, for example in the form of a threaded structure.

The holding component may adopt a load-bearing function. In one embodiment, the holding component is designed to adopt a load-bearing function for the mirror body. In an EUV mirror system having a frame structure on which the mirror body is supported, some of the forces transmitted between the frame structure and the mirror body may be transmitted by way of the holding component. A connection element extending between the frame structure and the mirror body may engage the holding component. In other embodiments, the holding component may be designed to support itself or an element such as a sensor attached to the mirror body.

The observation channel may extend through the transparent material of the mirror body between the viewing window and the adhesive bond. The mirror body material may be transparent to visible light in particular. The holding component may consist of a non-transparent material, and so the observation channel ends at the holding component. This configuration is particularly favorable for the detection of defects in the adhesive bond because the non-transparent material of the holding component provides the observer with an unambiguous orientation as regards the plane in which the adhesive bond can be found.

The optical surface may be formed on a front side of the mirror body. The mirror body may have a rear side opposite the front side. The observation channel may extend between the front side and the rear side of the mirror body. An observation channel axis may intersect the front side of the mirror body in a region of the front side adjacent to the optical surface. A region adjacent to the optical surface is a region of the front side which is not used for shaping an EUV beam path during the operation of the EUV mirror.

In one embodiment, the holding component is attached to the front side of the mirror body, in particular in such a way that it is accessible from the front side of the mirror body. The viewing window may be formed on the rear side of the mirror body such that the observation channel extends from the rear side to the holding component. In another embodiment, the holding component is attached to the rear side of the mirror body, in particular in such a way that it is accessible from the rear side of the mirror body. The viewing window may be formed on the front side of the mirror body such that the observation channel extends from the front side to the holding component.

In addition to that or in an alternative, it is also possible for the viewing window to be formed on a lateral surface of the pin. Starting from the lateral surface of the pin, an observation channel incident on the adhesive bond surface at an angle may extend as far as the adhesive bond. The viewing window may extend without interruption over the entire circumference of the pin. In the axial direction, the viewing window may extend over a part of the pin or over the entire length thereof.

There may be cases in which an observer has no easy access to the position from where the observation channel extends through the viewing window to the adhesive bond. In order to nevertheless enable an examination of the adhesive bond, provision may be made for a deflection mirror at which the direction of the observation channel is deflected. The deflection mirror may be attached to the mirror body or be positioned relative to the mirror body without a direct physical connection. The invention encompasses a mirror body having a deflection mirror attached thereto and an EUV mirror system having a mirror body and a deflection mirror, in which the deflection mirror is held at a predetermined position relative to the mirror body.

The adhesive bond between the holding component and the mirror body may cover a continuous area. In the case of a bushing adhesively bonded to a pin, for example, the adhesive bond may extend in the form of a closed ring over the end face of the pin and over the collar of the bushing. Alternatively, the adhesive bond may cover multiple separated areas. The adhesive bond between the holding component and the mirror body is formed by multiple separate adhesive regions in that case. In all cases, the mirror body and the viewing window may be embodied such that the entirety of the adhesive bond can be examined.

The connection surface of the mirror body to which the adhesive bond adheres may be a plane surface. The adhesive bond may cover the whole of the plane surface or parts thereof. Projections that define the area of the adhesive bond may be formed on the surface. Adhesive pads may be formed by the projections. In addition to that or in an alternative, the same may apply to the area of the holding component on which the adhesive bond is formed.

The inspection of the adhesive bond may be carried out as a quality assurance step during the production of the EUV mirror. The adhesive bond may also be inspected during maintenance or an overhaul of the EUV mirror.

The inspection can be performed by a person who brings their eye into a suitable position such that the adhesive bond becomes visible along the observation channel. Typical adhesive bond defects such as incomplete coverage of the intended area or foreign inclusions may be detected in this way.

The optical surface of the mirror body may be formed by a highly reflective coating. This may be a multilayer coating, in particular a multilayer coating having alternating layers of molybdenum and silicon, such that the optical surface is provided with high reflectivity for EUV radiation. The term “EUV radiation” denotes electromagnetic radiation in the extreme ultraviolet spectral range with wavelengths between 5 nm and 30 nm. In particular, the EUV radiation may have a wavelength of 13.5 nm.

In addition to that or in an alternative, an image sensor positioned at a suitable position relative to the observation channel may record an image of the adhesive bond in order to enable an inspection of the adhesive bond. The image may be examined for adhesive bond defects by a person or by way of an automated image evaluation. The invention also relates to an inspection system comprising an EUV mirror according to the invention and an image sensor, wherein the image sensor is designed to record an image of the adhesive bond through the observation channel.

The invention also relates to a mask inspection apparatus comprising an illumination system and a projection lens. The illumination system is designed to guide EUV radiation emitted by an EUV radiation source onto a photomask such that the photomask is illuminated with uniform brightness. The projection lens is designed to image the photomask onto an image sensor of an EUV camera. At least one of the EUV mirrors off which the EUV radiation is reflected between the EUV radiation source and the image sensor is embodied as an EUV mirror according to the invention.

The invention also relates to a method for examining an EUV mirror. The EUV mirror comprises a mirror body and a holding component. The holding component is connected to the mirror body by way of an adhesive bond. An optical surface with high reflectivity for EUV radiation is formed on the mirror body. The mirror body consists of a transparent material, wherein the surface of the mirror body comprises a non-transparent surface region and a viewing window. The adhesive bond is examined by way of an observation channel which extends through the viewing window to the adhesive bond.

The disclosure encompasses developments of the method with features that are described in the context of the EUV mirror according to the invention. The disclosure encompasses developments of the EUV mirror with features that are described in the context of the method according to the invention.

### DESCRIPTION OF DRAWINGS

The invention is described by way of example below on the basis of advantageous embodiments and with reference to the accompanying drawings, in which:

FIG. 1: shows a schematic illustration of a mask inspection apparatus according to the invention;

FIG. 2: shows a schematic illustration of an EUV mirror according to the invention;

FIG. 3: shows a detail of the EUV mirror from FIG. 2 in an enlarged illustration;

FIGS. 4, 5: show an embodiment of the invention;

FIGS. 6, 7: show the view according to FIGS. 4, 5 in the case of an alternative embodiment of the invention;

FIGS. 8, 9: show further embodiments of the invention.

### DETAILED DESCRIPTION

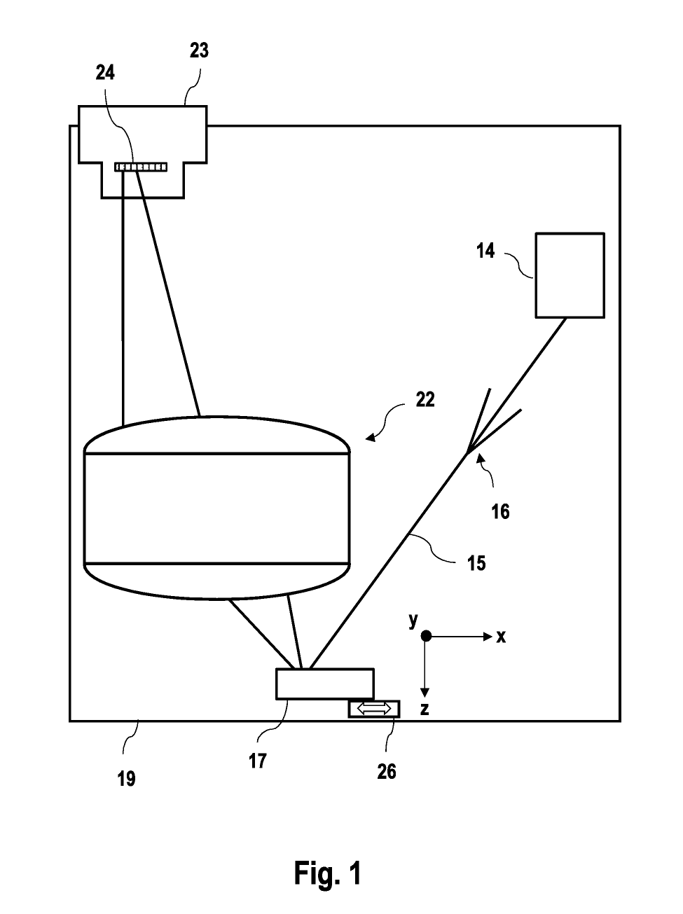

Microlithographic photomasks 17 can be examined using a mask inspection apparatus as shown in FIG. 1.

In general, microlithographic photomasks 17 are intended to be used in a microlithographic projection exposure apparatus (not illustrated). In the microlithographic projection exposure apparatus, the photomask 17 is illuminated with extreme ultraviolet radiation (EUV radiation) at a wavelength of for example 13.5 nm in order to image a structure formed on the photomask 17 onto the surface of a lithographic object in the form of a wafer. The wafer is coated with a photoresist that reacts to the EUV radiation. The mask inspection apparatus is used to examine whether the photomask meets the requirements and is defect free.

In accordance with FIG. 1, the photomask 17 is arranged in the mask inspection apparatus such that an EUV beam path 15 emanating from an EUV radiation source 14 is guided onto the photomask 17 via an illumination system 16. The illumination system 16 is used to shape the EUV radiation to form a beam used to illuminate, with uniform brightness, an examination field on the surface of the photomask 17. The illumination system 16 can include one or more optical elements, e.g., one or more EUV mirrors used to shape the EUV beam path from the EUV radiation source 14 to the photomask 17. The illuminated region may have dimensions of 0.5 mm x 0.8 mm, for example. A field stop used to restrict the illuminated region to the examination field on the surface of the photomask 17 is arranged in the illumination system 16. Using a positioning system 26, it is possible to move the photomask in the xy-plane in order to bring different examination fields on the surface of the photomask 17 into the region of the EUV beam path 15. The EUV radiation source 14 can be, e.g., a plasma radiation source, in which the EUV radiation is emitted from a plasma at a wavelength of, e.g., 13.5 nm. For example, tin is a medium that can be used to generate a plasma suitable for emitting such EUV radiation. A laser beam can be made to impinge on a droplet of the medium for the purpose of creating the plasma.

The edge lengths of the photomask 17 may be between 100 mm and 200 mm, for example. The photomask may have an aspect ratio between 1:1 and 1:3, preferably between 1:1 and 1:2 and particularly preferably of 1:1 or 1:2. The photomask may be configured to be substantially rectangular. The photomask may preferably have a length and a width of 5 to 7 inches (12.7 cm to 17.8 cm), particularly preferably a length and a width of 6 inches (15.2 cm). Alternatively, the photomask may have a length of 5 to 7 inches (12.7 cm to 17.8 cm) and a width of 10 to 14 inches (25.4 cm to 35.6 cm), preferably a length of 6 inches (15.2 cm) and a width of 12 inches (30.5 cm).

The EUV beam path 15 reflected off the photomask 17 continues through a projection lens 22 to an EUV camera 23, which is equipped with an image sensor 24. The image sensor 24 can include, e.g., a charged coupled device (CCD) sensor or a complementary metal oxide semiconductor (CMOS) sensor. The image sensor 24 can include, e.g., an array of individually addressable sensing elements of pixels. The projection lens 22 is used to image the examination field on the surface of the photomask 17 onto the image sensor 24 of the EUV camera 23. The projection lens 22 can include one or more optical elements, e.g., one or more EUV mirrors used to shape the EUV beam path from the photomask 17 to the image sensor 24. The EUV radiation source 14, the illumination system 16, the photomask 17, the projection lens 22 and the EUV camera 23 are arranged in a vacuum housing 19, in which there is negative pressure during the operation of the mask inspection apparatus.

The illumination system 16 and the projection lens 22 comprise multiple optical elements, including EUV mirrors used to shape the EUV beam path. Precise positioning of the EUV mirror elements is required to achieve a high imaging quality of the mask inspection apparatus.

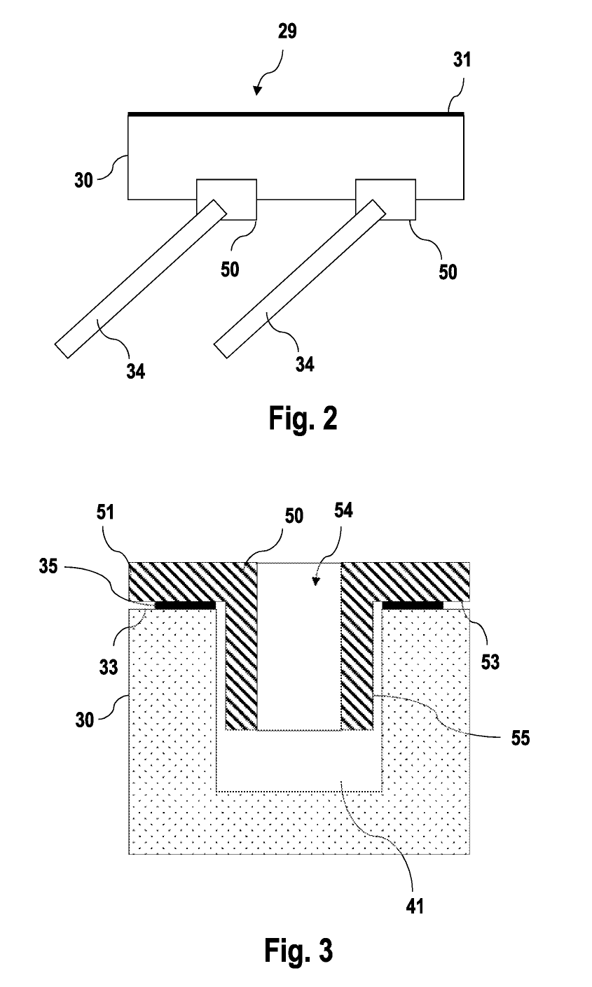

FIG. 2 shows a schematic illustration of an EUV mirror 29 from the mask inspection apparatus of FIG. 1. The EUV mirror 29 comprises a mirror body 30 and an optical surface 31 formed on the mirror body 30. The EUV mirror is held on a frame structure (not illustrated) of the mask inspection apparatus by way of multiple connection elements 34. Each connection element 34 engages on a bushing 50 which is fastened to the mirror body 30. Every bushing 50 forms a holding component within the meaning of the invention.

FIG. 3 shows a sectional illustration of one of the bushings 50. The bushing 50 comprises a bushing collar 51 which projects outwardly vis-à-vis a shaft 55. The shaft 55 is recessed in a cutout 41 of the mirror body 30. The bushing collar 51 is placed on a surface of the mirror body 30. A receptacle 54 provided with a threaded structure (not shown) is formed in the interior of the shaft 55. The threaded structure is used to screw the associated connection element 34 to the bushing 50. Other types of connections between the connection element 34 and the bushing 50 are also possible.

The underside of the bushing collar 51 is formed as a bearing surface 53. An adhesive bond 35 between the bushing 50 and a connection surface 33 on the mirror body 30 is established on the bearing surface 53. A defect-free adhesive bond 35 is required for reliable operation of the optical system. The invention provides the option of checking the quality of the adhesive bond 35 during the production of an EUV mirror 29. A direct visual inspection of the adhesive bond 35 is not readily possible because the adhesive bond 35 is concealed by the bushing collar 51.

The mirror body 30 consists of a material that is transparent to visible light. However, owing to mechanical processing steps, the surface of the mirror body 30 away from the optical surface 31 has a structure at which visible light is scattered. Despite the material being transparent per se, a clear view through the mirror body is not possible on account of the surface structure of the mirror body 30. The invention proposes forming a viewing window 32 in the surface of the mirror body 30 in order to create an observation channel 33 which extends as far as the adhesive bond 35 from the viewing window 32.

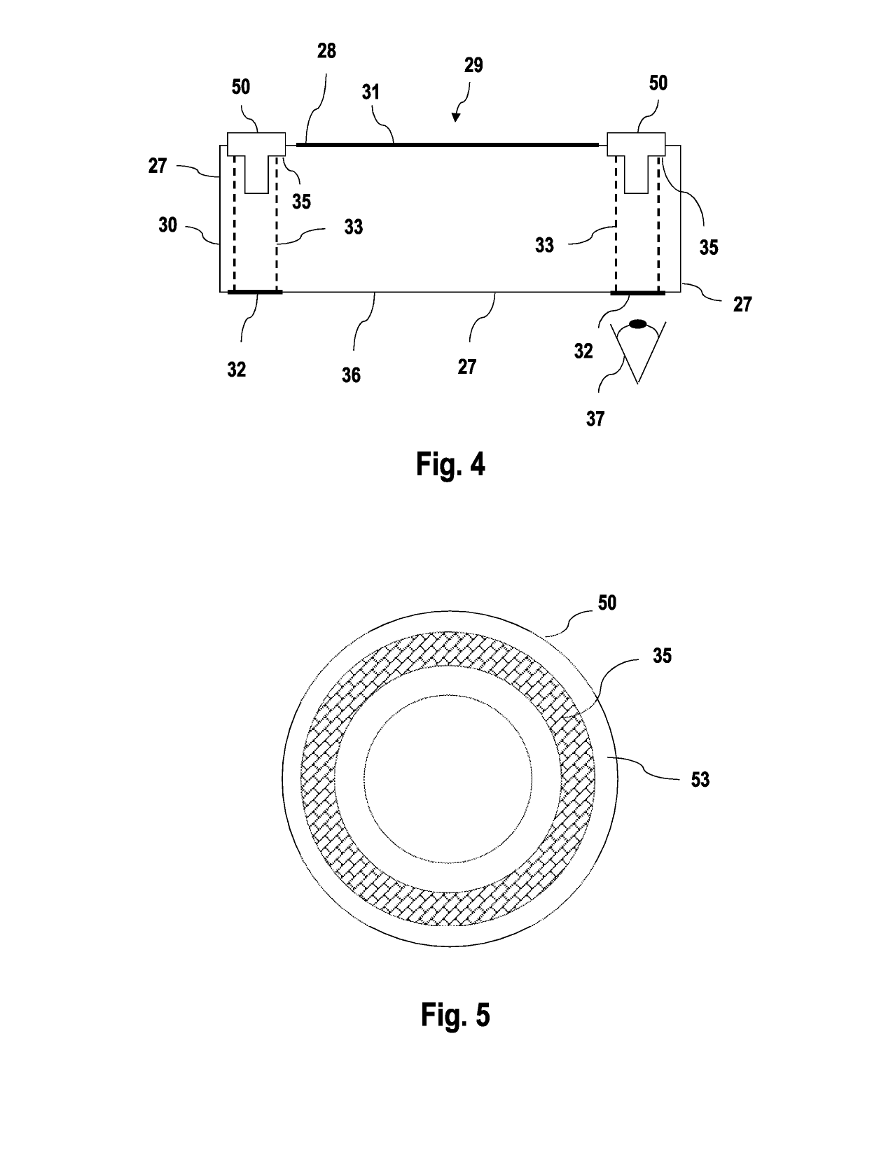

This is depicted in FIG. 4 on the basis of an exemplary embodiment in which the bushings 50 are attached adjacent to the optical surface 31 on the front side 28 of the mirror body 30. The adhesive bond 35 formed between the bushing 50 and the mirror body 30 extends in the form of a closed ring over the bearing surface 53 of the bushing 50. Two viewing windows 32 are formed on a rear side 36 opposite the front side 28 of the mirror body 30, with each viewing window 32 being opposite one of the bushings 50. An observation channel 33 indicated by dashed lines in FIG. 4 extends between a viewing window 32 and the associated bushing 50.

FIG. 4 also depicts an eye 37 of an observer arranged in front of one of the viewing windows 32. The observer looks through the viewing window 32 and has a direct view of the adhesive bond 35 between the bearing surface 53 of the bushing collar 51 and the connection surface 33 of the mirror body. The image seen by the observer substantially corresponds to the illustration in FIG. 5. Typical defects of an adhesive bond 35 such as an incomplete coverage of the intended adhesive area or inclusions within the adhesive can be detected by the observer. If the inspection is performed within the scope of maintenance or an overhaul of the mirror, further defects come into consideration, for example, a change in the adhesive as a result of ageing or a reaction with water. Such defects can also be detected by visual inspection.

A viewing window 32 in the surface of the mirror body 30 may be produced by processing the surface of the mirror body 30 such that the roughness is reduced. In one embodiment, the viewing window 32 is produced by polishing the surface of the mirror body 30 in the region in question.

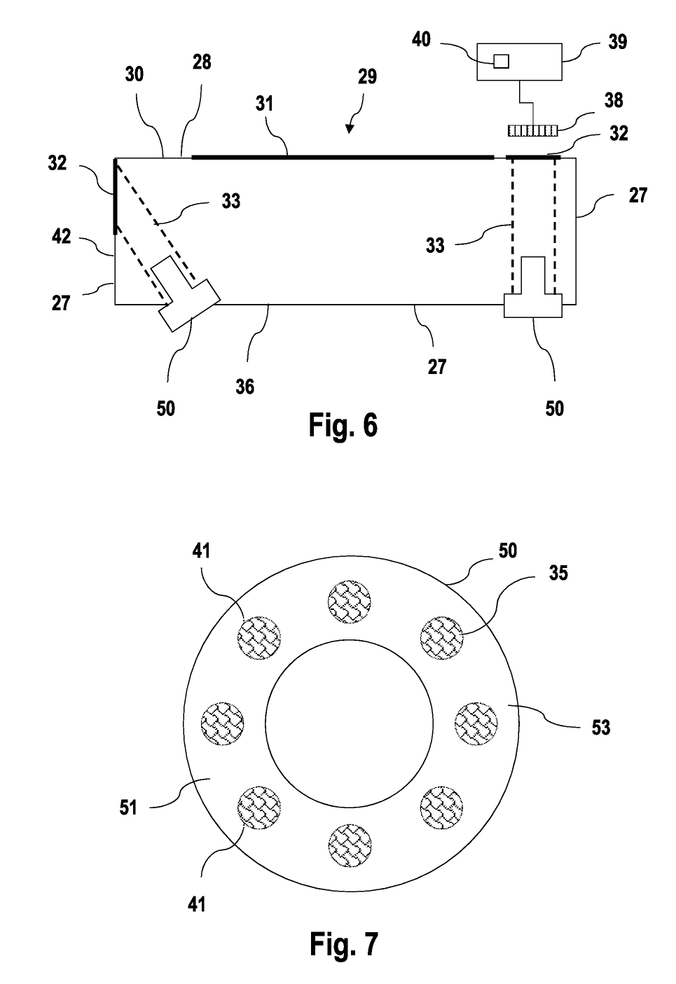

FIGS. 6, 7 show an alternative exemplary embodiment in which the bushings 50 are attached to the rear side 36 of the mirror body 30. One of the viewing windows 32 is formed adjacent to the optical surface 31 on the front side of the mirror body 30. A second viewing window 32 is formed in a side face 42 of the mirror body 30. Both viewing windows 32 are arranged such that a clear view of the bearing surface 53 of the bushing collar 51 is rendered possible. In this case, the adhesive bond 35 is formed by a plurality of adhesive pads 41 which are uniformly distributed over the circumference of the bushing collar 51.

In addition to direct visual inspection, there is the option of detecting the state of the adhesive bond 35 in an automated process. An image sensor 38 used to record an image of the adhesive bond 35 is arranged in front of one of the viewing windows 32. The image is supplied to a computing unit 39, in which the image data are evaluated. A pattern corresponding to a defect-free adhesive bond 35 and used for a comparison with the recorded image is stored in a memory element 40 of the computing unit 39. An error message is generated if the computing unit 39 identifies a deviation from the desired state of the adhesive bond 35, and the EUV mirror 29 may be supplied for a closer examination.

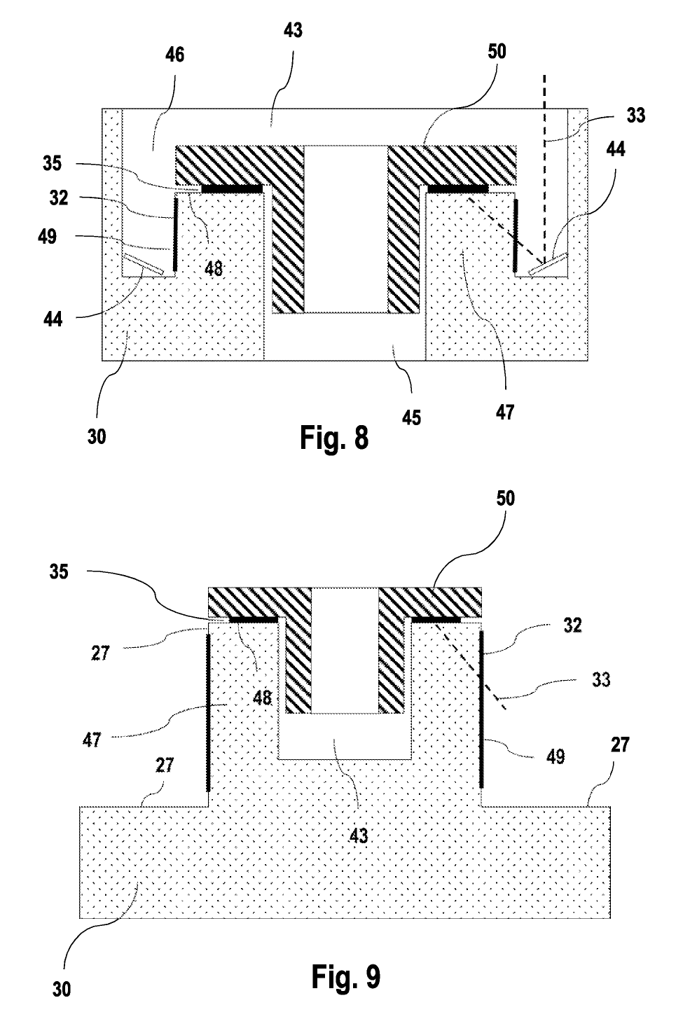

In the exemplary embodiment according to FIG. 8, the bushing 50 is recessed within the mirror body 30. A cutout 43 comprising a central through-bore 45 and a ring-shaped depression 46 extending around the through-bore 45 is formed in the mirror body 30. A pin 47 with an end face 48 remains between the through-bore 45 and the ring-shaped depression 46. The end face 48 of the pin 47 forms the connection surface used to establish the adhesive bond 35 to the bushing 50. The end face 48 is recessed so deeply within the mirror body 30 that the bushing 50 attached to the pin 47 is also recessed within the mirror body 30. The bushing 50 lies completely within a contour spanned by the mirror body 30.

The viewing window 32 opening up the observation channel 33 to the adhesive bond 35 is formed in the lateral surface 49 of the pin 47. The viewing window 32 extends without interruption over the entire circumference of the pin 47 and covers the lateral surface in its entirety. The clear view of the adhesive bond 35 through the viewing window 32 is provided from a position which is located within the ring-shaped depression 46 and which is difficult to reach.

In order to facilitate the view of the adhesive bond 35, a deflection mirror 44 extending in the form of a closed ring over the entire circumference of the pin 47 is arranged at the base of the ring-shaped depression 46. The observation channel 33 extends from a position above the mirror body 30 to the adhesive bond 35 via the deflection mirror 44.

In the embodiment according to FIG. 9, the mirror body comprises a pin 47 which projects outwards from the mirror body 30. A cutout 43 into which the shaft of the bushing 50 projects is formed in the center of the pin 47. The viewing window 32 extends over the circumference of the lateral surface 49 of the pin 47. The quality of the adhesive bond can be examined via the observation channel 33 from a position adjacent to the lateral surface 49.

In some implementations, the computing unit 39 can include one or more computers (or computing devices), each computer can include one or more processor cores, and each processor core can include logic circuitry for processing data. For example, a processor can include an arithmetic and logic unit (ALU), a control unit, and various registers. Each processor can include cache memory. Each processor can include a system-on-chip (SoC) that includes multiple processor cores, random access memory, graphics processing units, one or more controllers, and one or more communication modules. Each processor can include millions or billions of transistors.

In some implementations, each of the one or more computers can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage medium or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

A number of embodiments of the invention have been described. Nevertheless, it will be understood that various modifications may be made without departing from the spirit and scope of the invention.

What is claimed is:

1. An EUV mirror, comprising a mirror body and a holding component, wherein the holding component is connected to the mirror body by way of an adhesive bond, wherein an optical surface with high reflectivity for EUV radiation is formed on the mirror body, wherein the mirror body comprises a transparent material, wherein the surface of the mirror body comprises a non-transparent surface region and a viewing window, and wherein the viewing window provides an observation channel to the adhesive bond.

2. The EUV mirror of claim 1, wherein the viewing window is formed by a polished surface region of the mirror body.

3. The EUV mirror of claim 1, wherein the holding component is attached to a pin of the mirror body.

4. The EUV mirror of claim 3, wherein the holding component is attached to an end face of the pin.

5. The EUV mirror of claim 3, wherein the holding component comprises a projection which projects into a cutout in the pin.

6. The EUV mirror of claim 1, wherein the holding component is in the form of a bushing.

7. The EUV mirror of claim 1, wherein the holding component comprises a non-transparent material such that the observation channel ends at the holding component.

8. The EUV mirror of claim 3, wherein the viewing window is formed on a lateral surface of the pin.

9. The EUV mirror of claim 1, wherein the observation channel extends between a front side and a rear side of the mirror body.

10. The EUV mirror of claim 1, comprising a deflection mirror, at which the direction of the observation channel is deflected.

11. An inspection system, comprising an EUV mirror and an image sensor, wherein the EUV mirror is embodied according to claim 1 and wherein the image sensor is designed to record an image of the adhesive bond through the observation channel.

12. A mask inspection apparatus, comprising an illumination system and a projection lens, wherein the illumination system is designed to guide EUV radiation emitted by an EUV radiation source onto a photomask such that the photomask is illuminated with uniform brightness, wherein the projection lens is designed to image the photomask onto an image sensor of an EUV camera, wherein at least one of the EUV mirrors off which the EUV radiation is reflected between the EUV radiation source and the image sensor is embodied according to claim 1.

13. A method for examining an EUV mirror, wherein the EUV mirror comprises a mirror body and a holding component, wherein the holding component is connected to the mirror body by way of an adhesive bond, wherein an optical surface with high reflectivity for EUV radiation is formed on the mirror body, wherein the mirror body consists of a transparent material, wherein the surface of the mirror body comprises a non-transparent surface region and a viewing window, and wherein the adhesive bond is examined by way of an observation channel which extends through the viewing window to the adhesive bond.

14. The mask inspection apparatus of claim 12, wherein the holding component is attached to a pin of the mirror body.

15. The mask inspection apparatus of claim 12, wherein the holding component is in the form of a bushing.

16. The mask inspection apparatus of claim 12, wherein the holding component comprises a non-transparent material such that the observation channel ends at the holding component.

17. The mask inspection apparatus of claim 12, wherein the observation channel extends between a front side and a rear side of the mirror body.

18. The method of claim 13, wherein the holding component is attached to a pin of the mirror body.

19. The method of claim 13, wherein the holding component is in the form of a bushing.

20. The method of claim 13, wherein the holding component comprises a non-transparent material such that the observation channel ends at the holding component.
